(19) United States
(12) Patent Application Publication
(10) Pub. No.: US 2023/0411540 A1
(43) Pub. Date: Dec. 21, 2023

(54) SEMICONDUCTOR DEVICE AND METHOD OF MAKING

(71) Applicant: Taiwan Semiconductor Manufacturing Company Limited, Hsin-Chu (TW)

(72) Inventors: Yi-Hsuan FAN, New Taipei City (TW); Wen-Sheng WANG, Hsin-Chu (TW); Yen-Ting CHEN, Changhua County (TW)

(21) Appl. No.: 17/842,672

(22) Filed: Jun. 16, 2022

(51) Int. Cl. H01L 31/0216; H01L 31/102

(52) U.S. Cl. CPC H01L 31/02161; H01L 31/102

(57) ABSTRACT

A semiconductor device is provided. The semiconductor device includes one or more dielectric layers over a photodiode in a substrate. The semiconductor device includes a radiation channeling structure extending through the one or more dielectric layers, wherein the radiation channeling structure overlies the photodiode. The semiconductor device includes a lens overlying the radiation channeling structure. The radiation channeling structure includes a body having a refractive index higher than a refractive index of a material at least partially surrounding the body.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12 illustrates a cross-sectional view of a semiconductor device, in accordance with some embodiments.

FIG. 13 illustrates a cross-sectional view of a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor device has a photodiode in a substrate, a lens overlying the photodiode, and one or more dielectric layers between the photodiode and the lens. The semiconductor device includes a radiation channeling structure extending through the one or more dielectric layers. Radiation incident upon the lens is channeled by the radiation channeling structure to the photodiode. The radiation channeling structure increases an amount of radiation that is at least one of sensed, detected, or converted to electrons by the photodiode, as compared to semiconductor devices that do not have the radiation channeling structure.

A body of the radiation channeling structure has a refractive index higher than a refractive index of a material at least partially surrounding the body. Radiation is channeled and/or guided through the radiation channeling structure to the photodiode, such as due, at least in part, to the refractive index of the body being higher than the refractive index of the material at least partially surrounding the body. In some embodiments, the radiation channeling structure provides for an increase in an amount of radiation that is at least one of sensed, detected, or converted to electrons by the photodiode, as compared to other sensors that do not have the radiation channeling structure. In some embodiments, the increase in the amount of the radiation that is at least one of sensed, detected or converted to electrons by the photodiode is due, at least in part, to more of the radiation being channeled to the photodiode and less of the radiation being at least one of consumed or absorbed by the one or more dielectric layers between the photodiode and the lens. As compared to the semiconductor device that implements the radiation channeling structure, in other sensors that do not have the radiation channeling structure, more radiation is consumed and/or absorbed by the one or more dielectric layers between the lens and the photodiode. In some embodiments, the radiation channeling structure at least one of prevents or mitigates crosstalk between the photodiode and one or more other photodiodes, such as due, at least in part, to the radiation channeling structure channeling and/or guiding radiation incident upon the lens to the photodiode, thereby providing for a reduced amount of radiation incident upon the lens that travels away from the photodiode to a different photodiode.

In some embodiments, a first portion of the radiation channeling structure has at least one of a first tapered sidewall or a second tapered sidewall. The first portion of the radiation channeling structure having at least one of the first tapered sidewall or the second tapered sidewall directs more radiation to the photodiode as compared to a structure that does not have the first tapered sidewall or the second tapered sidewall. In some embodiments, a structure not having a tapered sidewall scatters or reflects more radiation away from the photodiode as compared to the first portion of the radiation channeling structure having at least one of the first tapered sidewall or the second tapered sidewall.

Implementing the radiation channeling structure between the photodiode and the lens provides for an increased quantum efficiency (QE) as compared with semiconductor devices not having the radiation channeling structure. In some embodiments, the semiconductor device operates as a sensor, such as at least one of an image sensor, a proximity sensor, or a different type of sensor. Given the increased QE, the semiconductor device operates more efficiently than other sensors, such as requiring less power, detecting more light in relatively low light environments, etc.

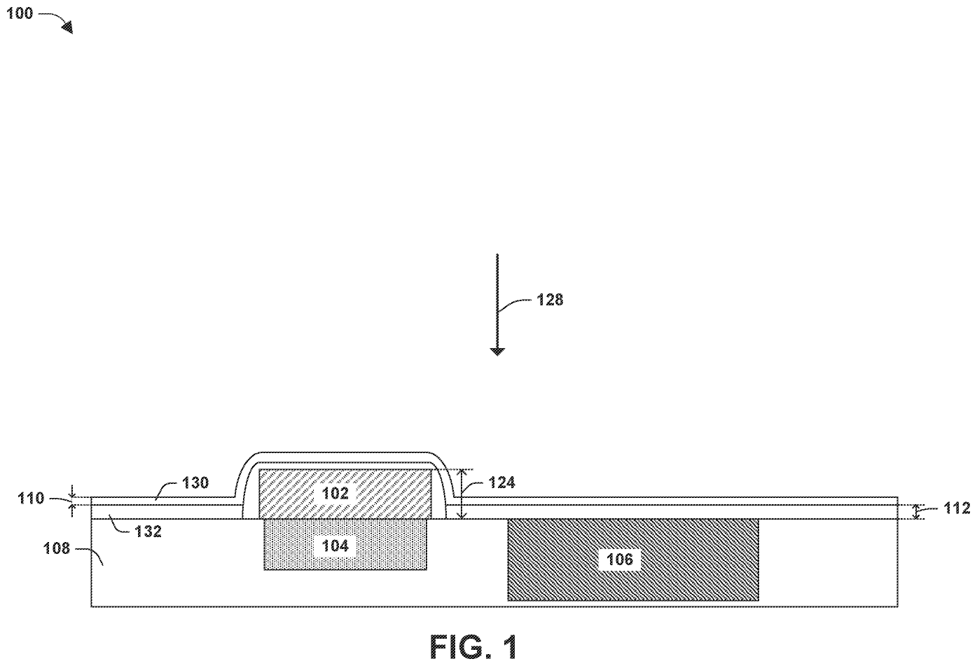

FIGS. 1-12 illustrate cross-sectional views of a semiconductor device 100 at various stages of fabrication, in accordance with some embodiments. In some embodiments, a sensor is implemented via the semiconductor device 100. The sensor comprises at least one of an image sensor, a complementary metal-oxide-semiconductor (CMOS) image sensor, a proximity sensor, a time of flight (ToF) sensor, an indirect ToF (iToF) sensor, a backside illumination (BSI) sensor, a backside CMOS image sensor, or another type of sensor. Other structures and/or configurations of the semiconductor device 100 and/or the sensor are within the scope of the present disclosure.

FIG. 1 illustrates the semiconductor device 100 according to some embodiments. The semiconductor device 100 comprises at least one of a substrate 108, a photodiode 106 in the substrate 108, a polysilicon structure 102, a memory unit 104, a protective layer 132, or an etch stop layer 130.

The substrate 108 comprises at least one of an epitaxial layer, a silicon-on-insulator (SOI) structure, a wafer, or a die formed from a wafer. The substrate 108 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP or other suitable material. In some embodiments, the substrate 108 comprises at least one of monocrystalline silicon, crystalline silicon with a <100> crystallographic orientation, crystalline silicon with a <110> crystallographic orientation, crystalline silicon with a <111> crystallographic orientation or other suitable material. The substrate 108 has at least one doped region. Other structures and/or configurations of the substrate 108 are within the scope of the present disclosure.

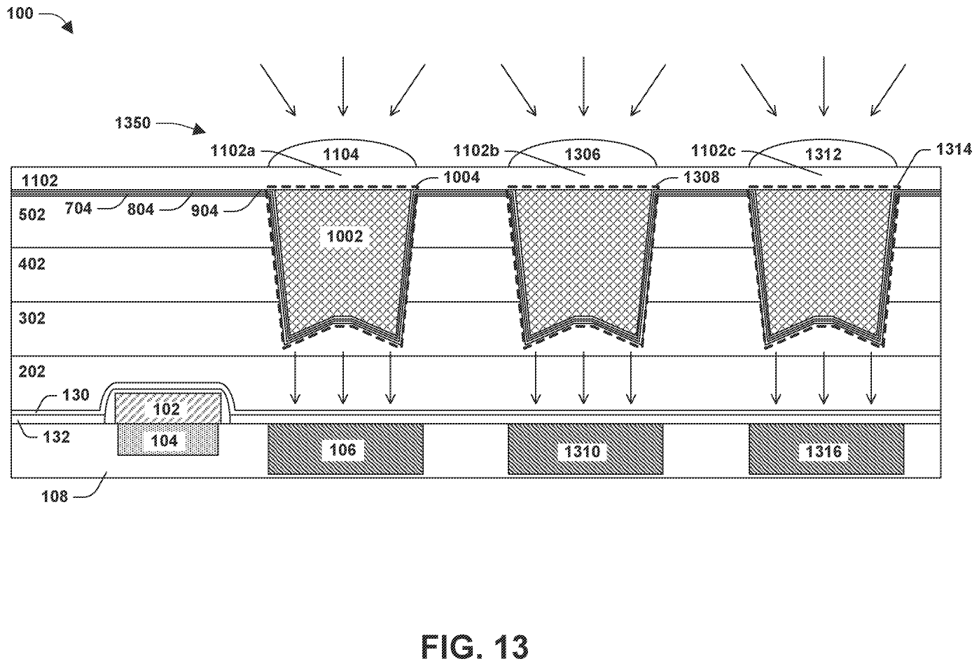

In some embodiments, the photodiode 106 is disposed in the substrate 108. The photodiode 106 is formed by at least one of doping, ion implantation, molecular diffusion, or other suitable techniques. The photodiode comprises at least one of a pinned layer photodiode, a phototransistor, a photogate, or other suitable type of photodiode. In some embodiments, the semiconductor device 100 comprises multiple photodiodes (such as shown in FIG. 13), where at least some of the multiple photodiodes can vary from one another to have at least one of different heights, thicknesses, widths, material compositions, etc. Any number of the multiple photodiodes in the substrate 108 are contemplated. The photodiode 106 comprises at least one of germanium, indium, phosphorous, boron, BF₂, arsenic, antimony, fluorine, InAs, InSb, GaSb, GaAs, InP, a silicide, or other suitable material. The photodiode 106 is configured to sense radiation, such as incident light, which is projected towards the semiconductor device 100 along direction 128. Other structures and/or configurations of the photodiode 106 are within the scope of the present disclosure.

In some embodiments, the memory unit 104 is disposed in the substrate 108. The memory unit 104 is formed by at least one of doping, ion implantation, molecular diffusion, or other suitable techniques. In some embodiments, the polysilicon structure 102 is formed over at least one of the memory unit 104 or the substrate 108. The polysilicon structure 102 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques. The polysilicon structure 102 at least one of overlies the memory unit 104, is in direct contact with the memory unit 104, or is in indirect contact with the memory unit 104. In some embodiments, the polysilicon structure 102 is grown on top of the memory unit 104. Other structures and/or configurations of the polysilicon structure 102 relative to other elements, features, etc. are within the scope of the present disclosure. The polysilicon structure 102 has a thickness 124 between about 1,000 angstroms to about 3,000 angstroms (such as between about 1,800 angstroms to about 2,000 angstroms). Other values of the thickness 124 are within the scope of the present disclosure.

In some embodiments, the protective layer 132 is formed over the substrate 108. The protective layer 132 is formed by at least one of PVD, sputtering, CVD, PECVD, LPCVD, ALCVD, UHVCVD, RPCVD, ALD, MBE, LPE, spin on, growth, or other suitable techniques. The protective layer 132 at least one of overlies the substrate 108, is in direct contact with the substrate 108, or is in indirect contact with the substrate 108. The protective layer 132 comprises at least one of an oxide semiconductor material, such as silicon dioxide, or other suitable material. In some embodiments, the protective layer 132 comprises a resist protective oxide (RPO) layer. In some embodiments, the protective layer 132 is used to prevent dopants from escaping a region, in the substrate 108, into which the dopants were implanted. In some embodiments, one or more thermal treatment processes are performed to activate the dopants. Without the protective layer 132, the dopants may escape the region during the one or more thermal treatment processes performed to activate the dopants. In some embodiments, the protective layer 132 prevents at least some of the dopants from escaping the region during the one or more thermal treatment processes. The dopants comprise at least one of p+ dopants, boron, or other types of dopants. Other structures and/or configurations of the protective layer 132 are within the scope of the present disclosure. The protective layer 132 has a thickness 112 between about 50 angstroms to about 1,000 angstroms (such as between about 200 angstroms to about 300 angstroms). Other values of the thickness 112 are within the scope of the present disclosure.

In some embodiments, the etch stop layer 130 is formed over the protective layer 132. The etch stop layer 130 is formed by at least one of PVD, sputtering, CVD, PECVD, LPCVD, ALCVD, UHVCVD, RPCVD, ALD, MBE, LPE, spin on, growth, or other suitable techniques. The etch stop layer 130 at least one of overlies the protective layer 132, is in direct contact with the protective layer 132, or is in indirect contact with the protective layer 132. In some embodiments, the etch stop layer 130 is used to stop one or more etching processes performed during fabrication of the semiconductor device 100. In some embodiments, the one or more etching processes are performed to form at least one of one or more vias, wiring, etc. in the semiconductor device 100. The etch stop layer 130 comprises at least one of an oxide semiconductor material, such as silicon dioxide, a nitride semiconductor material, such as silicon nitride, or other suitable material. Other structures and/or configurations of the etch stop layer 130 are within the scope of the present disclosure. The etch stop layer 130 has a thickness 110 between about 100 angstroms to about 2,000 angstroms (such as between about 500 angstroms to about 1,200 angstroms). Other values of the thickness 110 are within the scope of the present disclosure.

In some embodiments, one or more first dielectric layers are formed over at least one of the substrate 108, the protective layer 132, or the etch stop layer 130. The one or more first dielectric layers comprise at least one of one or more inter-metal dielectric (IMD) layers, one or more interlayer dielectric (ILD) layers, or one or more other dielectric layers. In some embodiments, the one or more first dielectric layers comprise at least one of a first dielectric layer 202, a second dielectric layer 302, a third dielectric layer 402, a fourth dielectric layer 502, or other dielectric layer.

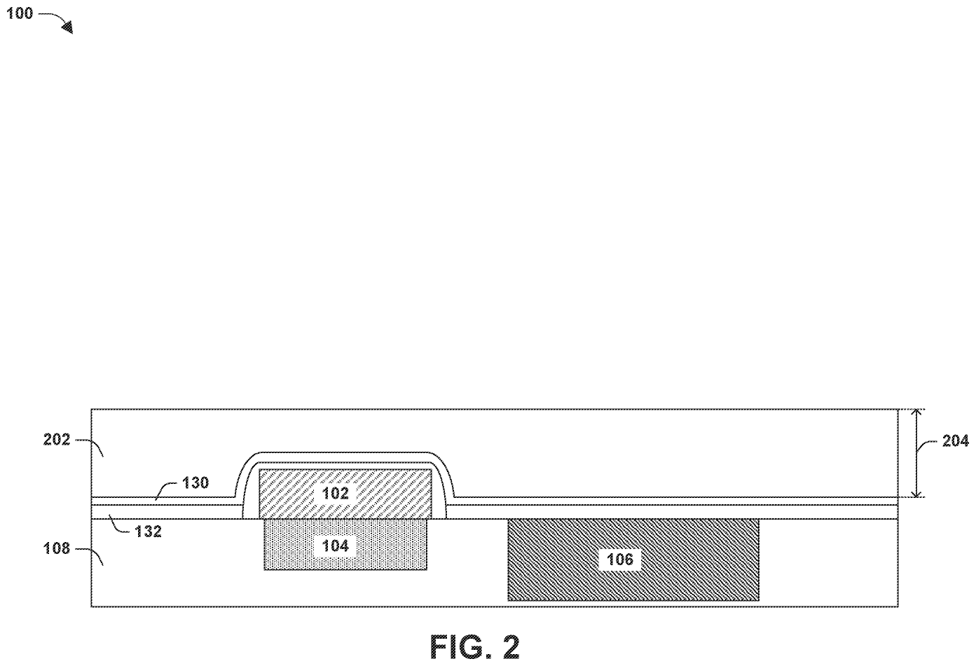

FIG. 2 illustrates the first dielectric layer 202 formed over at least one of the substrate 108, the protective layer 132, or the etch stop layer 130, according to some embodiments. The first dielectric layer 202 is formed by at least one of PVD, sputtering, CVD, PECVD, LPCVD, ALCVD, UHVCVD, RPCVD, ALD, MBE, LPE, spin on, growth, or other suitable techniques. The first dielectric layer 202 at least one of overlies the etch stop layer 130, is in direct contact with the etch stop layer 130, or is in indirect contact with the etch stop layer 130. The first dielectric layer 202 comprises at least one of an oxide semiconductor material, such as silicon dioxide, or other suitable material. In some embodiments, the first dielectric layer 202 comprises an ILD layer. Other structures and/or configurations of the first dielectric layer 202 are within the scope of the present disclosure. The first dielectric layer 202 has a thickness 204 of at least about 3,000 angstroms (such as at least about 4,000 angstroms). Other values of the thickness 204 are within the scope of the present disclosure.

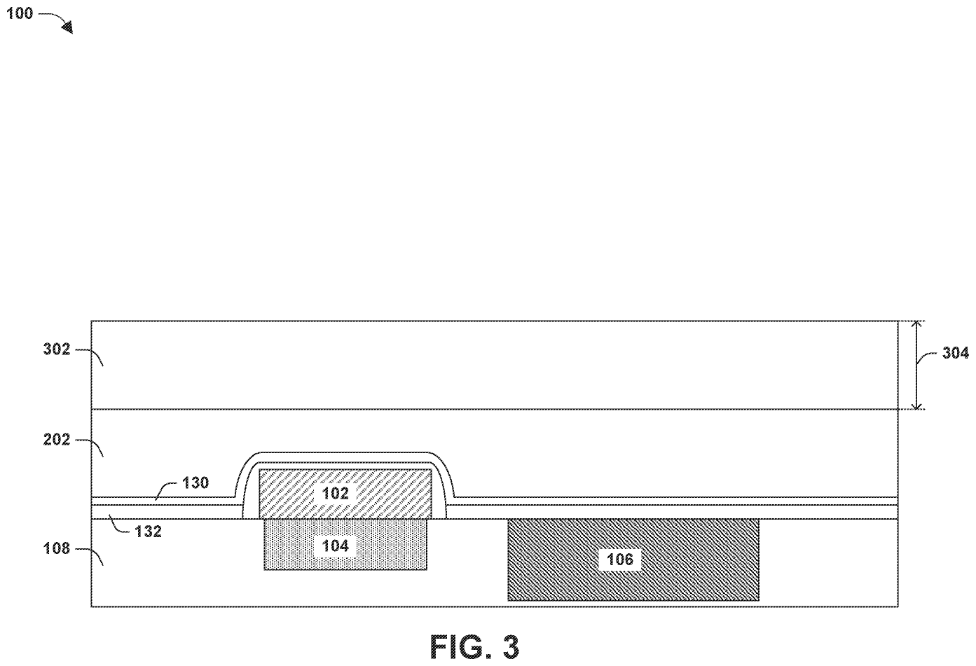

FIG. 3 illustrates the second dielectric layer 302 formed over the first dielectric layer 202, according to some embodiments. The second dielectric layer 302 is formed by at least one of PVD, sputtering, CVD, PECVD, LPCVD, ALCVD, UHVCVD, RPCVD, ALD, MBE, LPE, spin on, growth, or other suitable techniques. The second dielectric layer 302 overlies the first dielectric layer 202. The second dielectric layer 302 comprises at least one of an oxide semiconductor material, such as silicon dioxide, or other suitable material. In some embodiments, the second dielectric layer 302 comprises a first IMD layer. Other structures and/or configurations of the second dielectric layer 302 are within the scope of the present disclosure. The second dielectric layer 302 has a thickness 304 of at least about 3,000 angstroms (such as at least about 4,000 angstroms). Other values of the thickness 304 are within the scope of the present disclosure.

In some embodiments, the second dielectric layer 302 is in direct contact with a top surface of the first dielectric layer 202. The second dielectric layer 302 is different than the first dielectric layer 202, such as having a different material composition, such that an interface is defined between the second dielectric layer 302 and the first dielectric layer 202. In some embodiments, the second dielectric layer 302 does not have a material composition different than the first dielectric layer 202. An interface is nevertheless defined between the second dielectric layer 302 and the first dielectric layer 202 because the second dielectric layer 302 and the first dielectric layer 202 are separate, different, etc. layers. In some embodiments, the second dielectric layer 302 is in indirect contact with the top surface of the first dielectric layer 202, where one or more layers, such as a buffer layer, are between the second dielectric layer 302 and the first dielectric layer 202.

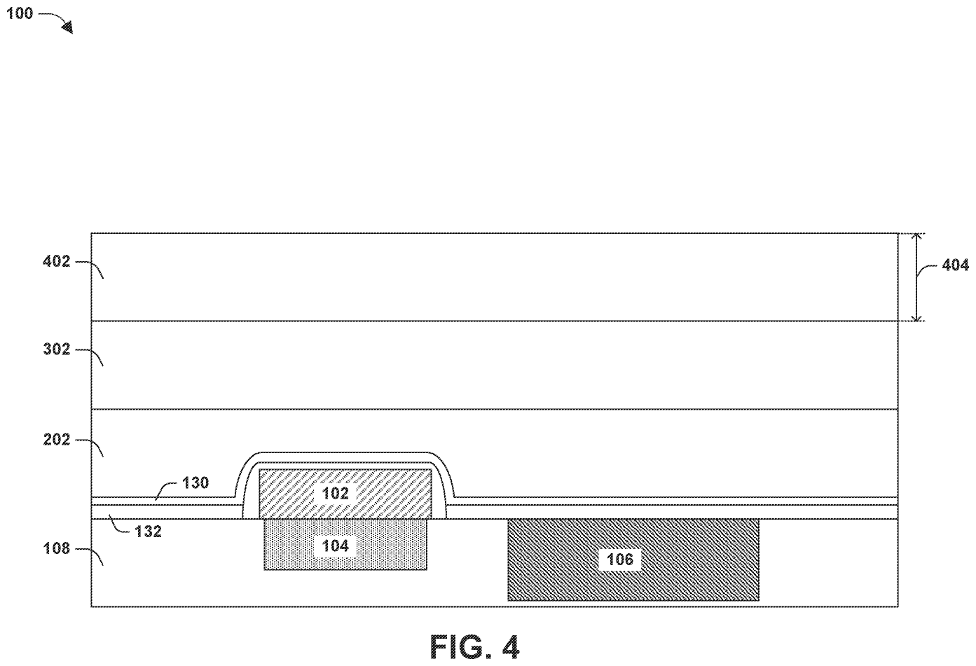

FIG. 4 illustrates the third dielectric layer 402 formed over the second dielectric layer 302, according to some embodiments. The third dielectric layer 402 is formed by at least one of PVD, sputtering, CVD, PECVD, LPCVD, ALCVD, UHVCVD, RPCVD, ALD, MBE, LPE, spin on, growth, or other suitable techniques. The third dielectric layer 402 overlies the second dielectric layer 302. The third dielectric layer 402 comprises at least one of an oxide semiconductor material, such as silicon dioxide, or other suitable material. In some embodiments, the third dielectric layer 402 comprises a second IMD layer. Other structures and/or configurations of the third dielectric layer 402 are within the scope of the present disclosure. The third dielectric layer 402 has a thickness 404 of at least about 3,000 angstroms (such as at least about 4,000 angstroms). Other values of the thickness 404 are within the scope of the present disclosure.

In some embodiments, the third dielectric layer 402 is in direct contact with a top surface of the second dielectric layer 302. The third dielectric layer 402 third dielectric layer 402 is different than the second dielectric layer 302, such as having a different material composition, such that an interface is defined between the third dielectric layer 402 and the second dielectric layer 302. In some embodiments, the third dielectric layer 402 does not have a material composition different than the second dielectric layer 302. An interface is nevertheless defined between the third dielectric layer 402 and the second dielectric layer 302 because the third dielectric layer 402 and the second dielectric layer 302 are separate, different, etc. layers. In some embodiments, the third dielectric layer 402 is in indirect contact with the top surface of the second dielectric layer 302, where one or more layers, such as a buffer layer, are between the third dielectric layer 402 and the second dielectric layer 302.

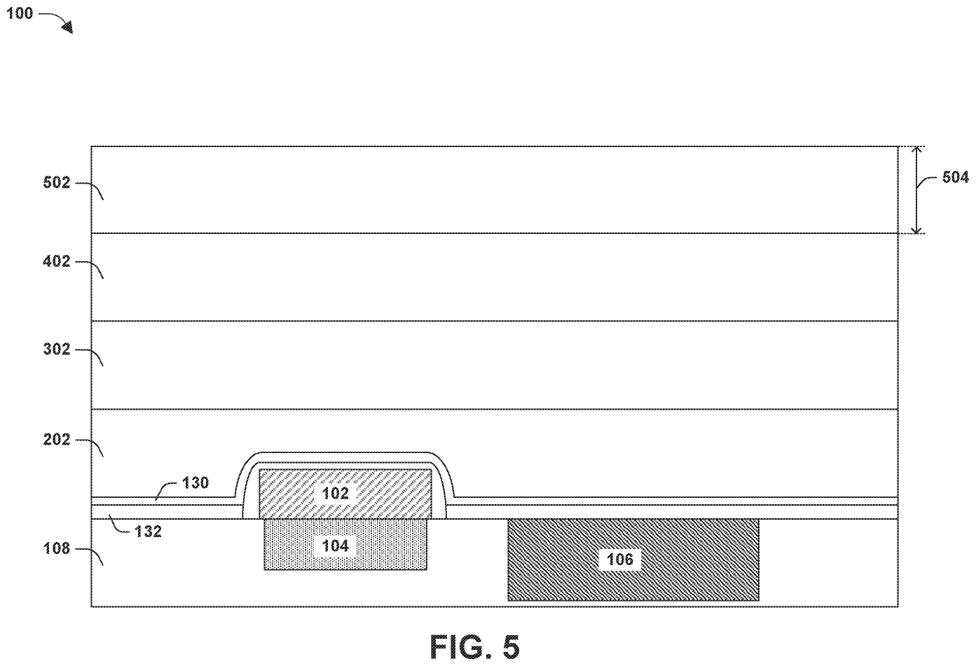

FIG. 5 illustrates the fourth dielectric layer 502 formed over the third dielectric layer 402, according to some embodiments. The fourth dielectric layer 502 is formed by at least one of PVD, sputtering, CVD, PECVD, LPCVD, ALCVD, UHVCVD, RPCVD, ALD, MBE, LPE, spin on, growth, or other suitable techniques. The fourth dielectric layer 502 overlies the third dielectric layer 402. The fourth dielectric layer 502 comprises at least one of an oxide semiconductor material, such as silicon dioxide, or other suitable material. In some embodiments, the fourth dielectric layer 502 comprises a passivation layer. Other structures and/or configurations of the fourth dielectric layer 502 are within the scope of the present disclosure. The fourth dielectric layer 502 has a thickness 504 of at least about 3,000 angstroms (such as at least about 4,000 angstroms). Other values of the thickness 504 are within the scope of the present disclosure.

In some embodiments, the fourth dielectric layer 502 is in direct contact with a top surface of the third dielectric layer 402. The fourth dielectric layer 502 is different than the third dielectric layer 402, such as having a different material composition, such that an interface is defined between the fourth dielectric layer 502 and the third dielectric layer 402. In some embodiments, the fourth dielectric layer 502 does not have a material composition different than the third dielectric layer 402. An interface is nevertheless defined between the fourth dielectric layer 502 and the third dielectric layer 402 because the fourth dielectric layer 502 and the third dielectric layer 402 are separate, different, etc. layers. In some embodiments, the fourth dielectric layer 502 is in indirect contact with the top surface of the third dielectric layer 402, where one or more layers, such as a buffer layer, are between the fourth dielectric layer 502 and the third dielectric layer 402.

In some embodiments, a trench 602 is formed through one or more second dielectric layers of the one or more first dielectric layers. In some embodiments, the trench 602 extends merely partially through the one or more second dielectric layers. Embodiments are contemplated in which the trench 602 extends completely through the one or more second dielectric layers. The one or more second dielectric layers comprise one, some, or all of the one or more first dielectric layers. In some embodiments, the one or more second dielectric layers comprise at least one of the first dielectric layer 202, the second dielectric layer 302, the third dielectric layer 402, the fourth dielectric layer 502, or other dielectric layer. In some embodiments, the one or more second dielectric layers comprise a subset of the one or more first dielectric layers, such as where the one or more second dielectric layers comprise at least one of the second dielectric layer 302, the third dielectric layer 402, or the fourth dielectric layer 502, and where the one or more second dielectric layers do not comprise the first dielectric layer 202.

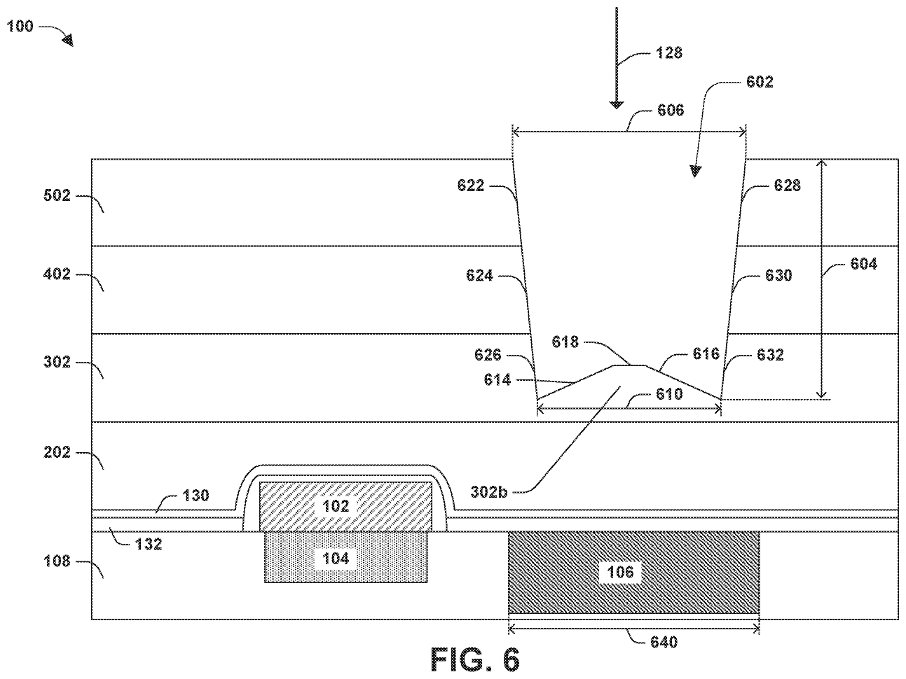

FIG. 6 illustrates the trench 602 formed through the one or more second dielectric layers, according to some embodiments in which the trench 602 extends though the second dielectric layer 302, the third dielectric layer 402 and the fourth dielectric layer 502. In some embodiments, the trench 602 extends completely through the fourth dielectric layer 502 and the third dielectric layer 402, and extends partially through the second dielectric layer 302. In some embodiments, the trench 602 does not reach or extend through the first dielectric layer 202. A portion of the second dielectric layer 302, a portion of the third dielectric layer 402 and a portion of the fourth dielectric layer 502 are removed to form the trench 602.

According to some embodiments, the trench 602 is formed using a photoresist (not shown). The photoresist is formed over the fourth dielectric layer 502 by at least one of PVD, sputtering, CVD, PECVD, LPCVD, ALCVD, UHVCVD, RPCVD, ALD, MBE, LPE, spin on, growth, or other suitable techniques. The photoresist comprises a light-sensitive material, where properties, such as solubility, of the photoresist are affected by light. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

In some embodiments, an etching process is performed to remove portions of the second dielectric layer 302, the third dielectric layer 402 and the fourth dielectric layer 502 to form the trench 602, where an opening in the photoresist allows one or more etchants applied during the etching process to remove portions of the second dielectric layer 302, the third dielectric layer 402 and the fourth dielectric layer 502 to form the trench 602 while the photoresist protects or shields portions of the second dielectric layer 302, the third dielectric layer 402 and the fourth dielectric layer 502 that are covered by the photoresist. The etching process is at least one of a dry etching process, a wet etching process, an anisotropic etching process, an isotropic etching process, or other suitable etching process. The etching process uses at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material. The photoresist is stripped or washed away after the trench 602 is formed. Other processes and/or techniques for forming the trench 602 are within the scope of the present disclosure.

In some embodiments, the trench 602 is formed to have a decreasing width along the direction 128, such as where a width 606 of an uppermost portion of the trench 602 is larger than a width 610 of a lowermost portion of the trench 602. In some embodiments, at least one of the width 606 of the uppermost portion of the trench 602 or the width 610 of the lowermost portion of the trench 602 are smaller than a width 640 of the photodiode 106. A bottom of the trench 602 is defined by at least one of a first tapered sidewall 614 of a portion 302b of the second dielectric layer 302, a second tapered sidewall 616 of the portion 302b of the second dielectric layer 302, or a surface 618 of the portion 302b of the second dielectric layer 302. At least one of the first tapered sidewall 614 has a first slope, such as a positive slope, or the second tapered sidewall 616 has a second slope, such as a negative slope. The second slope is opposite in polarity relative to the first slope. In some embodiments, the surface 618 extends between the first tapered sidewall 614 and the second tapered sidewall 616. In some embodiments, the first tapered sidewall 614, the second tapered sidewall 616, and the surface 618 form a convex shape. In some embodiments, at least one of the first tapered sidewall 614, the second tapered sidewall 616, or the convex shape are achieved by performing a dry etching process to form the trench 602. Sides of the trench 602 are defined by tapered sidewalls 626 and 632 of the second dielectric layer 302, tapered sidewalls 624 and 630 of the third dielectric layer 402, and/or tapered sidewalls 622 and 628 of the fourth dielectric layer 502. The trench 602 overlies the photodiode 106. In some embodiments, the entirety of the trench 602 is laterally coincident with the photodiode 106 such that no part of the trench 602 is laterally offset from the photodiode 106. Other structures and/or configurations of the trench 602 and/or the photodiode 106 relative to other elements, features, etc. are within the scope of the present disclosure. A vertical distance 604 between a top surface of the fourth dielectric layer 502 and a lowermost portion of the trench 602 is between about 10,000 angstroms to about 25,000 angstroms (such as between about 14,000 angstroms to about 20,000 angstroms). Other values of the vertical distance 604 are within the scope of the present disclosure.

In some embodiments, one or more third dielectric layers are formed in the trench 602. The one or more third dielectric layers may comprise at least one of a fifth dielectric layer 704, a sixth dielectric layer 804, a seventh dielectric layer 904, or other dielectric layer.

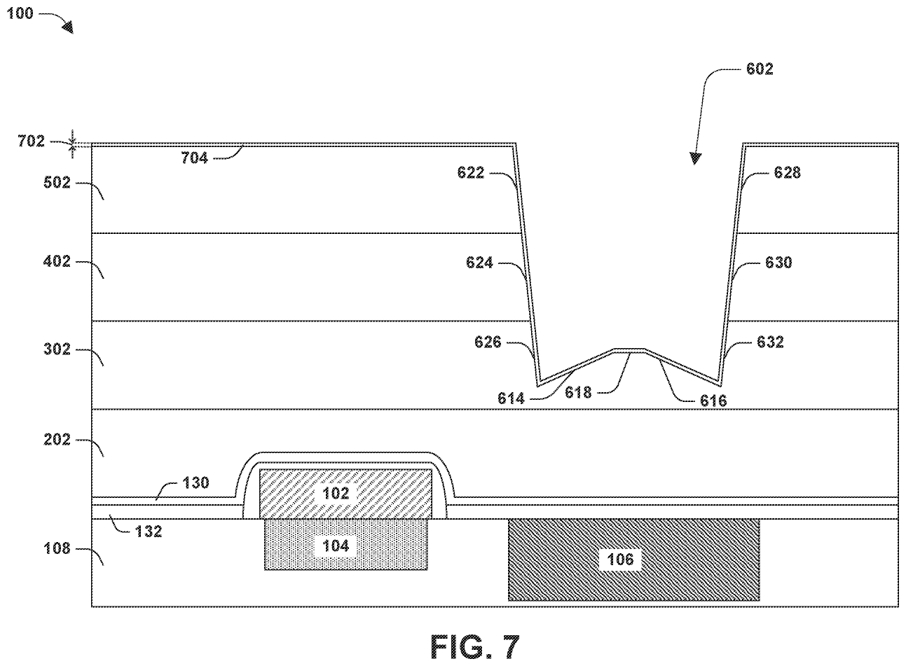

FIG. 7 illustrates the fifth dielectric layer 704 formed at least one of in the trench 602 or over the fourth dielectric layer 502, according to some embodiments. The fifth dielectric layer 704 is formed by at least one of PVD, sputtering, CVD, PECVD, LPCVD, ALCVD, UHVCVD, RPCVD, ALD, MBE, LPE, spin on, growth, or other suitable techniques. In some embodiments, the fifth dielectric layer 704 overlies the fourth dielectric layer 502. The fifth dielectric layer 704 comprises at least one of an oxide semiconductor material, such as silicon dioxide, or other suitable material. Other structures and/or configurations of the fifth dielectric layer 704 are within the scope of the present disclosure. The fifth dielectric layer 704 has a thickness 702 of at between about 50 angstroms to about 1,000 angstroms (such as between about 100 angstroms to about 700 angstroms). Other values of the thickness 702 are within the scope of the present disclosure.

In some embodiments, the fifth dielectric layer 704 is in direct contact with a top surface of the fourth dielectric layer 502. The fifth dielectric layer 704 is different than the fourth dielectric layer 502, such as having a different material composition, such that an interface is defined between the fifth dielectric layer 704 and the fourth dielectric layer 502. In some embodiments, the fifth dielectric layer 704 does not have a material composition different than the fourth dielectric layer 502. An interface is nevertheless defined between the fifth dielectric layer 704 and the fourth dielectric layer 502 because the fifth dielectric layer 704 and the fourth dielectric layer 502 are separate, different, etc. layers. In some embodiments, the fifth dielectric layer 704 is in indirect contact with the top surface of the fourth dielectric layer 502, where one or more layers, such as a buffer layer, are between the fifth dielectric layer 704 and the fourth dielectric layer 502. In some embodiments, the fifth dielectric layer 704 is at least one of in direct contact or in indirect contact with the tapered sidewalls 626 and 632 of the second dielectric layer 302, the tapered sidewalls 624 and 630 of the third dielectric layer 402, and/or the tapered sidewalls 622 and 628 of the fourth dielectric layer 502. Other structures and/or configurations of the fifth dielectric layer 704 relative to other elements, features, etc. are within the scope of the present disclosure.

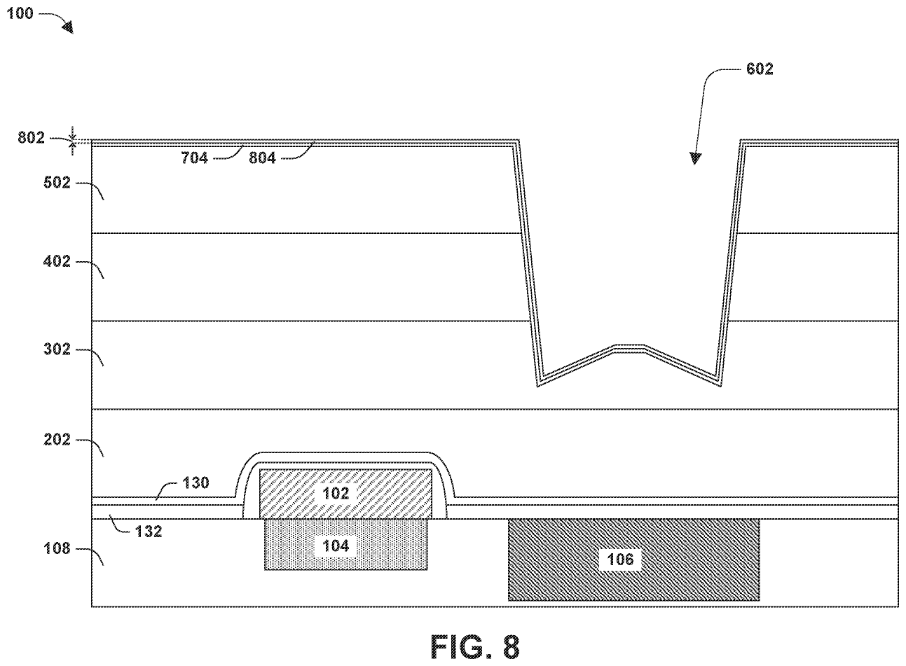

FIG. 8 illustrates the sixth dielectric layer 804 formed at least one of in the trench 602 or over the fifth dielectric layer 704, according to some embodiments. The sixth dielectric layer 804 is formed by at least one of PVD, sputtering, CVD, PECVD, LPCVD, ALCVD, UHVCVD, RPCVD, ALD, MBE, LPE, spin on, growth, or other suitable techniques. In some embodiments, the sixth dielectric layer 804 overlies the fifth dielectric layer 704. The sixth dielectric layer 804 comprises at least one of a nitride semiconductor material, such as silicon nitride, or other suitable material. Other structures and/or configurations of the sixth dielectric layer 804 are within the scope of the present disclosure. The sixth dielectric layer 804 at least one of overlies the fifth dielectric layer 704, is in direct contact with the fifth dielectric layer 704, or is in indirect contact with the fifth dielectric layer 704. The sixth dielectric layer 804 has a thickness 802 of at between about 50 angstroms to about 1,000 angstroms (such as between about 100 angstroms to about 700 angstroms). Other values of the thickness 802 are within the scope of the present disclosure.

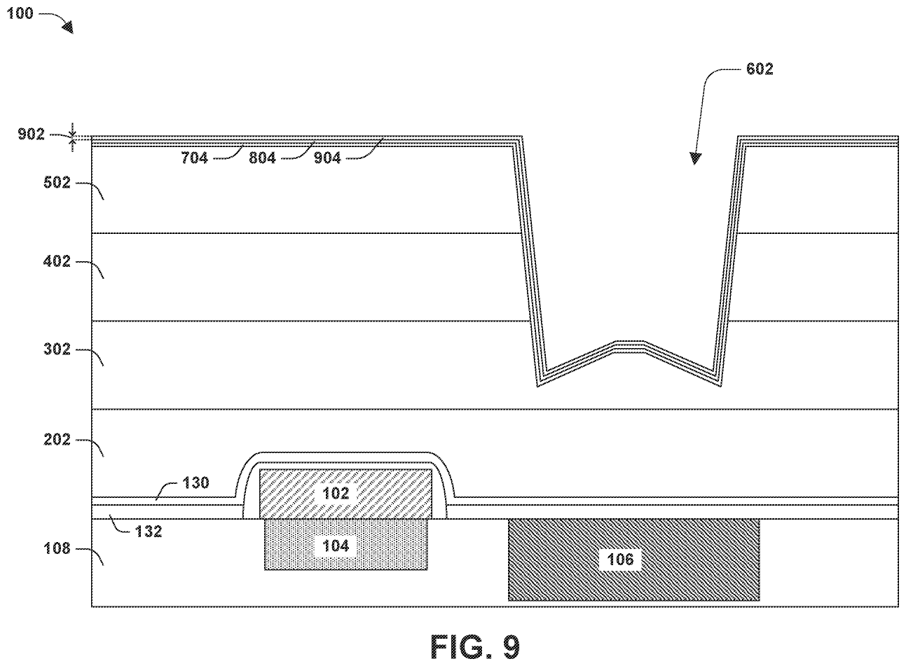

FIG. 9 illustrates the seventh dielectric layer 904 formed at least one of in the trench 602 or over the sixth dielectric layer 804, according to some embodiments. The seventh dielectric layer 904 is formed by at least one of PVD, sputtering, CVD, PECVD, LPCVD, ALCVD, UHVCVD, RPCVD, ALD, MBE, LPE, spin on, growth, or other suitable techniques. In some embodiments, the seventh dielectric layer 904 overlies the sixth dielectric layer 804. The seventh dielectric layer 904 comprises at least one of an oxide semiconductor material, such as silicon dioxide, or other suitable material. The seventh dielectric layer 904 at least one of overlies the sixth dielectric layer 804, is in direct contact with the sixth dielectric layer 804, or is in indirect contact with the sixth dielectric layer 804. Other structures and/or configurations of the seventh dielectric layer 904 are within the scope of the present disclosure. The seventh dielectric layer 904 has a thickness 902 of at between about 50 angstroms to about 1,000 angstroms (such as between about 100 angstroms to about 700 angstroms). Other values of the thickness 902 are within the scope of the present disclosure.

In some embodiments, the fifth dielectric layer 704 is a first oxide layer, such as a first silicon dioxide layer, the sixth dielectric layer 804 is a nitride layer, such as a silicon nitride layer, and the seventh dielectric layer 904 is a second oxide layer, such as a second silicon dioxide layer.

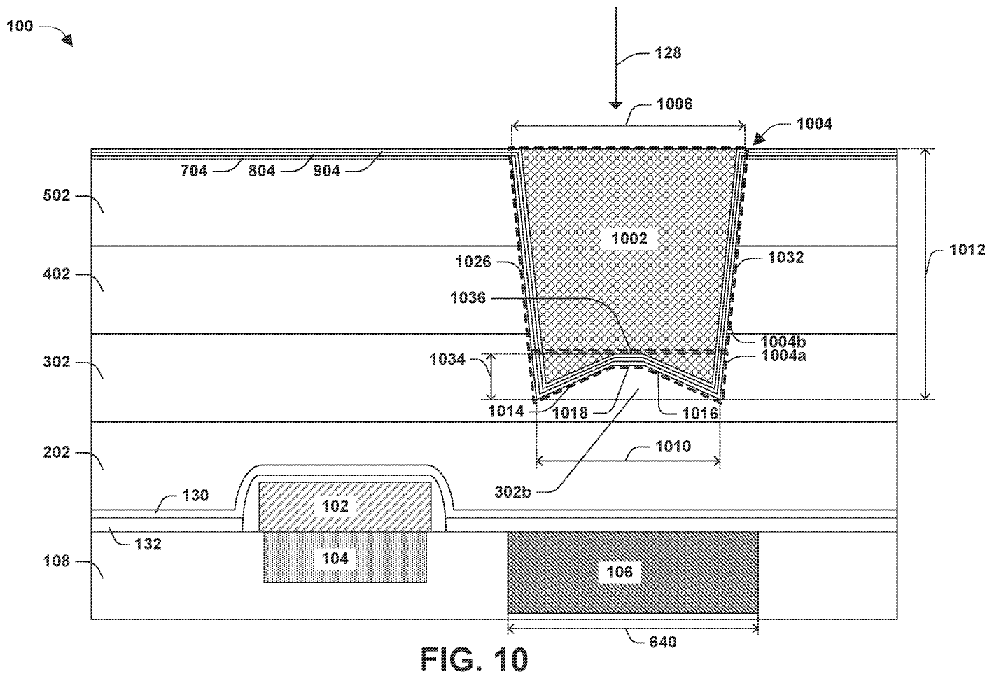

FIG. 10 illustrates a body 1002 formed in the trench 602, according to some embodiments. The body 1002 is formed by at least one of PVD, sputtering, CVD, PECVD, LPCVD, ALCVD, UHVCVD, RPCVD, ALD, MBE, LPE, spin on, growth, or other suitable techniques. In some embodiments, sidewalls of the body 1002 are at least one of aligned with, in direct contact with, or in indirect contact with a surface of the seventh dielectric layer 904. The body 1002 comprises a semiconductor material, such as at least one of silicon or other suitable material. In some embodiments, the body 1002 is formed by filling the trench 602 with the semiconductor material. The body 1002 has a refractive index higher than a threshold refractive index. In some embodiments, the threshold refractive index is between about 1.4 to about 3. Other values of the threshold refractive index are within the scope of the present disclosure. In some embodiments, the threshold refractive index is at least equal to a refractive index of a material at least partially surrounding the body 1002, such that the refractive index of the body 1002 is higher than the refractive index of the material at least partially surrounding the body 1002. In some embodiments, the material at least partially surrounding the body 1002 comprises material of at least one of the second dielectric layer 302, the third dielectric layer 402, the fourth dielectric layer 502, the fifth dielectric layer 704, the sixth dielectric layer 804, or the seventh dielectric layer 904. In some embodiments, the refractive index of the body 1002 is higher than at least one of a refractive index of the first dielectric layer 202, a refractive index of the second dielectric layer 302, a refractive index of the third dielectric layer 402, a refractive index of the fourth dielectric layer 502, a refractive index of the fifth dielectric layer 704, a refractive index of the sixth dielectric layer 804, or a refractive index of the seventh dielectric layer 904. Other structures and/or configurations of the body 1002 relative to other elements, features, etc. are within the scope of the present disclosure.

In some embodiments, the one or more third dielectric layers separate the body 1002 from the one or more second dielectric layers. The body 1002 and the one or more third dielectric layers form a radiation channeling structure 1004 (extending through the one or more second dielectric layers). Radiation is channeled and/or guided through the radiation channeling structure 1004 to the photodiode, such as due, at least in part, to the refractive index of the body 1002 being higher than the refractive index of the material at least partially surrounding the body 1002. Other structures and/or configurations of the radiation channeling structure 1004 are within the scope of the present disclosure.

In some embodiments, the radiation channeling structure 1004 is formed to have a decreasing width along the direction 128, such as where a width 1006 of an uppermost portion of the radiation channeling structure 1004 is larger than a width 1010 of a lowermost portion of the radiation channeling structure 1004. In some embodiments, at least one of the width 1006 of the uppermost portion of the radiation channeling structure 1004 or the width 1010 of the lowermost portion of the radiation channeling structure 1004 are smaller than the width 640 of the photodiode 106. A first portion 1004a, such as a bottom portion, of the radiation channeling structure 1004 is a first distance from the photodiode 106. An outline of the first portion 1004a of the radiation channeling structure 1004 is shown with a dashed line in FIG. 10. A second portion 1004b, such as a top portion, of the radiation channeling structure 1004 is a second distance from the photodiode 106. An outline of the second portion 1004b of the radiation channeling structure 1004 is shown with a dashed line in FIG. 10. The first distance is less than the second distance. The first portion 1004a of the radiation channeling structure 1004 has a first tapered sidewall 1014 with which the first tapered sidewall 614 (reference number 614 is shown in FIG. 6) of the second dielectric layer 302 is aligned. In some embodiments, the first tapered sidewall 1014 is a portion of a first surface of the fifth dielectric layer 704, such as a surface, of the fifth dielectric layer 704, that is in direct contact or indirect contact with the one or more second dielectric layers. The first portion 1004a of the radiation channeling structure 1004 has a surface 1018 with which the surface 618 (reference number 618 is shown in FIG. 6) of the second dielectric layer 302 is aligned. In some embodiments, the surface 1018 is a portion of the first surface of the fifth dielectric layer 704. The first portion 1004a of the radiation channeling structure 1004 has a second tapered sidewall 1016 with which the second tapered sidewall 616 (reference number 616 is shown in FIG. 6) of the second dielectric layer 302 is aligned. In some embodiments, the second tapered sidewall 1016 is a portion of the first surface of the fifth dielectric layer 704. At least one of the first tapered sidewall 1014 of the radiation channeling structure 1004 has a third slope, such as a positive slope, or the second tapered sidewall 1016 of the radiation channeling structure 1004 has a fourth slope, such as a negative slope. The fourth slope is opposite in polarity relative to the third slope. In some embodiments, the surface 1018 of the radiation channeling structure 1004 extends between the first tapered sidewall 1014 of the radiation channeling structure 1004 and the second tapered sidewall 1016 of the radiation channeling structure 1004. In some embodiments, the first tapered sidewall 1014 of the radiation channeling structure 1004, the second tapered sidewall 1016 of the radiation channeling structure 1004 and the surface 1018 of the radiation channeling structure 1004 form a convex shape. In some embodiments, at least some of the first portion 1004a of the radiation channeling structure 1004 and/or at least some of the portion 302b of the second dielectric layer 302 are an embedded lens structure, such as due, at least in part, to the radiation channeling structure 1004 having at least one of the first tapered sidewall 1014, the second tapered sidewall 1016, the surface 1018, the convex shape, etc. The semiconductor device 100 comprising the embedded lens structure results in more radiation being directed to the photodiode 106 underlying the embedded lens structure (as compared to an embodiment in which the radiation channeling structure 1004 does not have at least one of the first tapered sidewall 1014, the second tapered sidewall 1016, the surface 1018, the convex shape, etc.). Other structures and/or configurations of the radiation channeling structure 1004 are within the scope of the present disclosure.

In some embodiments, the radiation channeling structure 1004 has a third tapered sidewall 1026 and a fourth tapered sidewall 1032. At least one of the third tapered sidewall 1026 of the radiation channeling structure 1004 has a fifth slope, such as a negative slope, or the fourth tapered sidewall 1032 of the radiation channeling structure 1004 has a sixth slope, such as a positive slope. The sixth slope is opposite in polarity relative to the fifth slope. The third tapered sidewall 1026 is aligned with the tapered sidewall 626 of the second dielectric layer 302, the tapered sidewall 624 of the third dielectric layer 402, and/or the tapered sidewall 622 of the fourth dielectric layer 502 (reference numbers 626, 624 and 622 are shown in FIG. 6). The fourth tapered sidewall 1032 is aligned with the tapered sidewall 632 of the second dielectric layer 302, the tapered sidewall 630 of the third dielectric layer 402, and/or the tapered sidewall 628 of the fourth dielectric layer 502 (reference numbers 632, 630 and 628 are shown in FIG. 6). In some embodiments, the radiation channeling structure 1004 having the third tapered sidewall 1026 and the fourth tapered sidewall 1032 results in more radiation being directed to the photodiode 106 underlying the radiation channeling structure 1004 (as compared to an embodiment in which the radiation channeling structure 1004 does not have the third tapered sidewall 1026 or the fourth tapered sidewall 1032). Other structures and/or configurations of the radiation channeling structure 1004 are within the scope of the present disclosure.

A vertical distance 1012 between the uppermost portion of the radiation channeling structure 1004 and the lowermost portion of the radiation channeling structure 1004 is between about 10,000 angstroms to about 25,000 angstroms (such as between about 14,000 angstroms to about 20,000 angstroms). Other values of the vertical distance 1012 are within the scope of the present disclosure.

A vertical distance 1034 between an uppermost portion of the first portion 1004a of the radiation channeling structure 1004 and a lowermost portion of the first portion 1004a of the radiation channeling structure 1004 is between about 500 angstroms to about 4,000 angstroms (such as between about 500 angstroms to about 2,500 angstroms). In some embodiments, the uppermost portion of the first portion 1004a corresponds to a top surface 1036 of a portion of a top layer of the one or more third dielectric layers, such as a top surface of a portion, of the seventh dielectric layer 904, that overlies the surface 1018 of the radiation channeling structure 1004. Other values of the vertical distance 1034 are within the scope of the present disclosure. In some embodiments, the vertical distance 1034 corresponds to a height of the embedded lens structure.

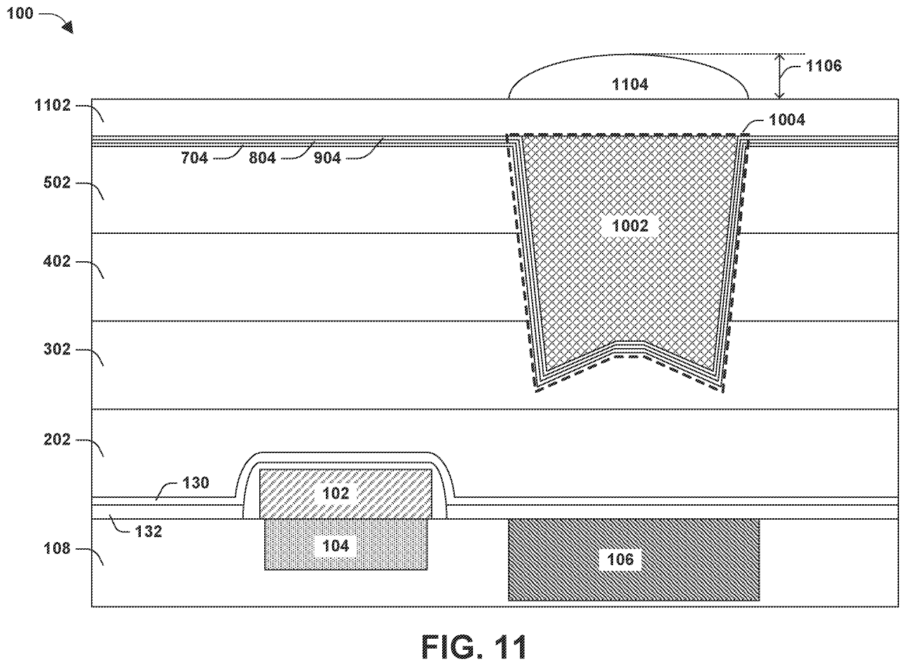

FIG. 11 illustrates a lens 1104 formed over at least one of the one or more third dielectric layers, the radiation channeling structure 1004, or the fourth dielectric layer 502, according to some embodiments. In some embodiments, the lens 1104 is at least one of a micro-lens or other suitable lens. In some embodiments, the lens 1104 has at least one of a half-spherical shape, a half-spheroidal shape, or other suitable shape. The lens 1104 overlies at least one of the radiation channeling structure 1004 or the photodiode 106. Other structures and/or configurations of the lens 1104 relative to other elements, features, etc. are within the scope of the present disclosure. A height 1106 of the lens 1104 is between about 10,000 angstroms to about 40,000 angstroms (such as between about 20,000 angstroms to about 30,000 angstroms). Other values of the height 1106 are within the scope of the present disclosure.

In some embodiments, the lens 1104 at least one of overlies a lens layer 1102, is in direct contact with a top surface of the lens layer 1102, or is in indirect contact with the top surface of the lens layer 1102. The lens layer 1102 at least one of overlies the seventh dielectric layer 904, is in direct contact with a top surface of the seventh dielectric layer 904, or is in indirect contact with the top surface of the seventh dielectric layer 904. The lens layer 1102 at least one of overlies the radiation channeling structure 1004, is in direct contact with a top surface of the radiation channeling structure 1004, or is in indirect contact with the top surface of the radiation channeling structure 1004. In some embodiments, the lens layer 1102 comprises a lens substrate comprising at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP or other suitable material. In some embodiments, the lens layer 1102 comprises one or more color filter layers. The one or more color filter layers comprise at least one of a pigment-dispersed color resist (PDCR) material, a photosensitive substance, a photoinitiator substance, a multifunctional monomer, one or more additives, a leveling agent, an adhesion promotor, resin, polymer soluble in alkaline solution, color paste, pigment, dispersant, solvent, or other suitable material. The one or more color filter layers filter certain wavelengths of radiation. In some embodiments, different portions of the one or more color filter layers have different material compositions to enable different wavelengths to be filtered. The lens layer 1102 is formed by at least one of PVD, sputtering, CVD, PECVD, LPCVD, ALCVD, UHVCVD, RPCVD, ALD, MBE, LPE, spin on, growth, or other suitable techniques. Other structures and/or configurations of the lens layer 1102 are within the scope of the present disclosure.

When the semiconductor device 100 does not comprise the lens layer 1102, the lens 1104 is at least one of in direct contact with the top surface of the radiation channeling structure 1004 or in indirect contact with the top surface of the radiation channeling structure 1004. In some embodiments, the lens 1104 is formed by at least one of thermal reflow, microplastic embossing, microdroplet jetting, photolithography, reactive ion etching, machining, or other suitable methods. Other structures and/or configurations of the lens 1104 are within the scope of the present disclosure.

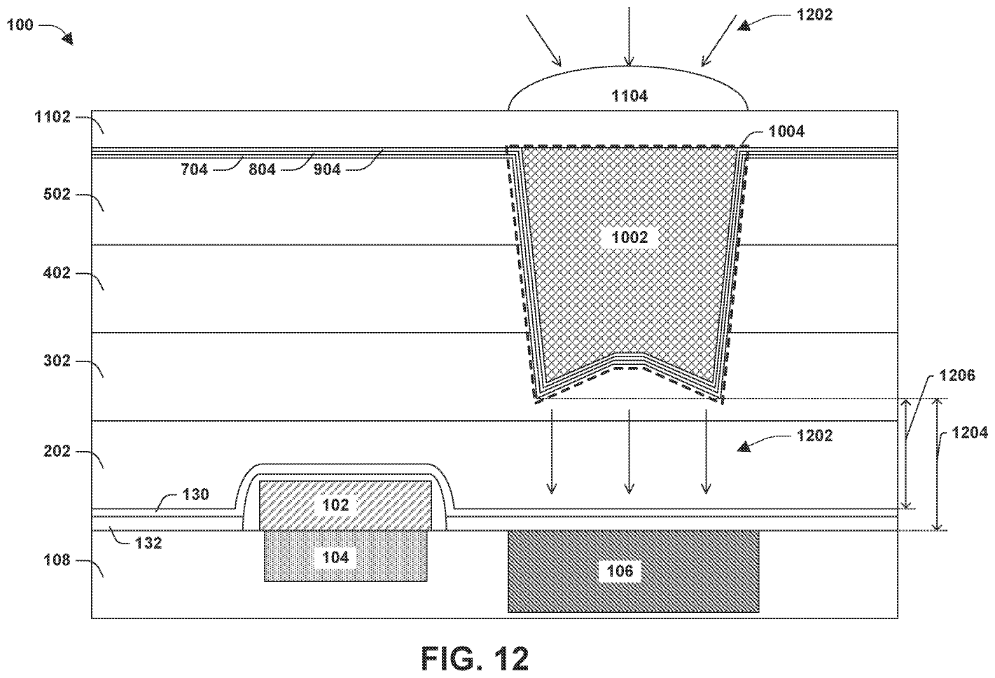

FIG. 12 illustrates a cross-sectional view of the semiconductor device 100, according to some embodiments. FIG. 12 illustrates radiation 1202 projected towards the semiconductor device 100. At least some of the radiation 1202 passes through at least one of the lens 1104, the lens layer 1102, the radiation channeling structure 1004, the second dielectric layer 302, the first dielectric layer 202, the etch stop layer 130, the protective layer 132, or some of the substrate 108, and is at least one of sensed, detected, or converted to electrons by the photodiode 106. The lens 1104 is configured to at least one of refract the radiation 1202, direct the radiation 1202 towards the radiation channeling structure 1004 underlying the lens 1104, or focus and concentrate the radiation 1202 onto the radiation channeling structure 1004. The radiation 1202 (that is incident upon the lens 1104) is channeled through the radiation channeling structure 1004 to the photodiode 106, such as due, at least in part, to the refractive index of the body 1002 being higher than the refractive index of material at least partially surrounding the body 1002, such as material of the seventh dielectric layer 904. In an embodiment where the material at least partially surrounding the body 1002 comprises silicon dioxide, the refractive index of the material at least partially surrounding the body 1002 is between about 1.4 and about 1.6. Other refractive indices of the material surrounding the body 1002 are within the scope of the present disclosure. In an embodiment where the body 1002 is a silicon body, the refractive index of the body 1002 is between about 3.3 and about 3.7. Other refractive indices of the body 1002 are within the scope of the present disclosure. At least one of the body 1002 or the material surrounding the body 1002 is configured to channel and/or guide the radiation 1202 towards the photodiode 106, such as due, at least in part, to the refractive index of the material surrounding the body 1002 being less than the refractive index of the body 1002.

In some embodiments, the radiation channeling structure 1004 provides for an increase in an amount of the radiation 1202 that is at least one of sensed, detected, or converted to electrons by the photodiode 106, as compared to other sensors that do not have the radiation channeling structure 1004. In some embodiments, the increase in the amount of the radiation 1202 that is at least one of sensed, detected or converted to electrons by the photodiode 106 is due, at least in part, to more of the radiation 1202 being channeled to the photodiode 106 and less of the radiation 1202 being at least one of consumed or absorbed by the one or more first dielectric layers. As compared to the semiconductor device 100 that implements the radiation channeling structure 1004, in other sensors that do not have the radiation channeling structure 1004, more of the radiation 1202 is consumed and/or absorbed by the one or more first dielectric layers between the lens 1104 and the photodiode 106. Implementing the radiation channeling structure 1004 mitigates reflection or deflection by the one or more first dielectric layers of radiation, projected towards the photodiode 106, away from the photodiode 106, such as due, at least in part, to the radiation channeling structure 1004 channeling and/or guiding the radiation 1202 to the photodiode 106 and/or due, at least in part, to the radiation channeling structure 1004 having at least one of the first tapered sidewall 1014, the second tapered sidewall 1016, the surface 1018, the convex shape, etc.

In some embodiments, the radiation channeling structure 1004 at least one of prevents or mitigates crosstalk between photodiodes in the semiconductor device 100, thereby providing for increased accuracy of the sensor (implemented by the semiconductor device 100). The radiation channeling structure 1004 at least one of prevents or mitigates the radiation 1202, incident upon the lens 1104, from traveling from the lens 1104 to a different photodiode other than the photodiode 106 that underlies the lens 1104. As compared to other sensors that do not have the radiation channeling structure 1004, due to the radiation channeling structure 1004, the radiation 1202 that is incident upon the lens 1104 is more likely to be channeled and/or guided to the photodiode 106 underlying the lens 1104 and/or is less likely to travel away from the photodiode 106 to a different photodiode associated with a different lens.

In some embodiments, the embedded lens structure (such as the first portion 1004a of the radiation channeling structure 1004 having at least one of the first tapered sidewall 1014, the second tapered sidewall 1016, the surface 1018, or the convex shape) provides for an increase in quantum efficiency (QE) as compared to other sensors that do not have the embedded lens structure of the radiation channeling structure 1004. The improvement in resolution and/or QE is due, at least in part, to the radiation 1202 being channeled, guided, refracted, concentrated, focused, directed, reflected, etc. toward the photodiode 106 by the embedded lens structure. Accordingly, the radiation channeling structure 1004 provides for an increase in radiation being sensed, detected, converted to electrons, etc. by the photodiode 106.

In some embodiments, electrons generated by the photodiode 106 are stored in the memory unit 104. In some embodiments, the electrons are stored in the memory unit 104 when a voltage is applied to the polysilicon structure 102. In some embodiments, the memory is accessed to determine information, such as an image or other type of information.

In some embodiments, the radiation channeling structure 1004 is separated from the photodiode 106 by a distance 1204 that is larger than a threshold distance to at least one of prevent or mitigate generation of dark current in the semiconductor device 100, such as current that is generated when there is no incident radiation, thereby providing for an increase in accuracy and/or resolution of the sensor (implemented by the semiconductor device 100) as compared to an embodiment in which the distance 1204 is smaller than the threshold distance. In some embodiments, if the distance 1204 is smaller than the threshold distance, an increased amount of dark current is generated in the semiconductor device 100, such as due, at least in part, to dangling bonds and/or extra electrons that are introduced to the semiconductor device 100 by the etching process performed to form the trench 602, such as where the dangling bonds and/or the extra electrons are introduced by plasma used for the etching process (such as a dry etching process). The threshold distance is between about 2,000 angstroms to about 5,000 angstroms. The distance 1204 is between about 2,000 angstroms to about 10,000 angstroms (such as between about 4,000 angstroms to about 7,000 angstroms). In some embodiments, a distance 1206 between the lowermost portion of the radiation channeling structure 1004 and a top surface of the etch stop layer 130 is between about 1,500 angstroms to about 9,000 angstroms, (such as between about 3,500 angstroms to about 6,500 angstroms). Other values of the threshold distance, the distance 1204, and/or the distance 1206 are within the scope of the present disclosure.

In some embodiments, the fifth dielectric layer 704, such as the first oxide layer, provides stress release to at least one of the sixth dielectric layer 804, the one or more second dielectric layers, or the body 1002 of the radiation channeling structure 1004. In some embodiments, the fifth dielectric layer 704, such as the first oxide layer, at least one of prevents or mitigates peeling of at least one of the sixth dielectric layer 804 or the one or more second dielectric layers. In some embodiments, the sixth dielectric layer 804, such as the nitride layer, at least one of prevents or mitigates generation of dark current in the semiconductor device 100, such as due, at least in part, to the sixth dielectric layer 804 at least one of covering or weakening dangling bonds and/or extra electrons that are introduced to the semiconductor device 100 by the etching process performed to form the trench 602, such as where the dangling bonds and/or the extra electrons are introduced by plasma used for the etching process (such as a dry etching process). In some embodiments, the seventh dielectric layer 904, such as the second oxide layer, is configured to provide improved adhesion of the body 1002 of the radiation channeling structure 1004 to the rest of the radiation channeling structure 1004.

FIG. 13 illustrates a cross-sectional view of the semiconductor device 100 according to some embodiments in which the semiconductor device 100 comprises at least one of multiple photodiodes, multiple radiation channeling structures, or multiple lenses of a lens array 1350. In some embodiments, for each photodiode of one, some and/or all photodiodes of the multiple photodiodes, the semiconductor device 100 comprises a radiation channeling structure overlying the photodiode, such as where the radiation channeling structure is between the photodiode and a lens overlying the photodiode. The multiple photodiodes comprise at least one of the photodiode 106, a second photodiode 1310, a third photodiode 1316, or one or more other photodiodes. The multiple radiation channeling structures comprise at least one of the radiation channeling structure 1004 (an outline of which is shown with a dashed line in FIG. 13) overlying the photodiode 106, a second radiation channeling structure 1308 (an outline of which is shown with a dashed line in FIG. 13) overlying the second photodiode 1310, a third radiation channeling structure 1314 (an outline of which is shown with a dashed line in FIG. 13) overlying the third photodiode 1316, or one or more other radiation channeling structures. The multiple lenses comprise at least one of the lens 1104 overlying the radiation channeling structure 1004, a second lens 1306 overlying the second radiation channeling structure 1308, a third lens 1312 overlying the third radiation channeling structure 1314, or one or more other radiation channeling structures.

In some embodiments, different photodiodes of the multiple photodiodes are configured to sense and/or detect different wavelengths of radiation. In some embodiments, at least one of the lens 1104 or a first portion 1102a of the lens layer 1102 underlying the lens 1104 has a material composition that allows first wavelengths to pass to the photodiode 106 while filtering wavelengths other than the first wavelengths. At least one of the second lens 1306 or a second portion 1102b of the lens layer 1102 underlying the second lens 1306 has a material composition that allows second wavelengths to pass to the second photodiode 1310 while filtering wavelengths other than the second wavelengths. At least one of the third lens 1312 or a third portion 1102c of the lens layer 1102 underlying the third lens 1312 has a material composition that allows third wavelengths to pass to the third photodiode 1316 while filtering wavelengths other than the third wavelengths. In some embodiments, when the sensor (implemented by the semiconductor device 100) is configured to detect radiation corresponding to RGB radiation, at least one of the first wavelengths comprise wavelengths corresponding to red, the second wavelengths comprise wavelengths corresponding to green, or the third wavelengths comprise wavelengths corresponding to blue. Other structures and/or configurations of the semiconductor device 100 are within the scope of the present disclosure.

In some embodiments, a semiconductor device is provided. The semiconductor device includes one or more dielectric layers over a photodiode in a substrate. The semiconductor device includes a radiation channeling structure extending through the one or more dielectric layers, wherein the radiation channeling structure overlies the photodiode. The semiconductor device includes a lens overlying the radiation channeling structure. The radiation channeling structure includes a body having a refractive index higher than a refractive index of a material at least partially surrounding the body.

In some embodiments, a semiconductor device is provided. The semiconductor device includes one or more dielectric layers over a photodiode in a substrate. The semiconductor device includes a radiation channeling structure extending through the one or more dielectric layers, wherein the radiation channeling structure overlies the photodiode. The semiconductor device includes a lens overlying the radiation channeling structure. A first portion of the radiation channeling structure is a first distance from the photodiode. A second portion of the radiation channeling structure is a second distance from the photodiode. The first distance is less than the second distance. The first portion of the radiation channeling structure has a first tapered sidewall with which a first tapered sidewall of a first dielectric layer of the one or more dielectric layers is aligned.

In some embodiments, a method for forming a semiconductor device is provided. The method includes forming a plurality of dielectric layers over a substrate. The method includes forming a trench through one or more dielectric layers of the plurality of dielectric layers. The trench overlies a photodiode in the substrate. A bottom of the trench is defined by a first tapered sidewall of a first dielectric layer of the one or more dielectric layers and a second tapered sidewall of the first dielectric layer. The first tapered sidewall of the first dielectric layer has a first slope. The second tapered sidewall of the first dielectric layer has a second slope. The second slope is opposite in polarity relative to the first slope. The method includes forming a plurality of layers, of a radiation channeling structure, in the trench, wherein the plurality of layers includes a first oxide layer, a second oxide layer, and a nitride layer between the first oxide layer and the second oxide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
one or more dielectric layers over a photodiode in a substrate;
a radiation channeling structure extending through the one or more dielectric layers, wherein the radiation channeling structure overlies the photodiode; and
a lens overlying the radiation channeling structure, wherein the radiation channeling structure comprises a body having a refractive index higher than a refractive index of a material at least partially surrounding the body.

2. The semiconductor device of claim 1, wherein:
a first portion of the radiation channeling structure is a first distance from the photodiode;
a second portion of the radiation channeling structure is a second distance from the photodiode;
the first distance is less than the second distance; and
the first portion of the radiation channeling structure has a first tapered sidewall with which a first tapered sidewall of a first dielectric layer of the one or more dielectric layers is aligned.

3. The semiconductor device of claim 2, wherein:
the first portion of the radiation channeling structure has a second tapered sidewall with which a second tapered sidewall of the first dielectric layer is aligned.

4. The semiconductor device of claim 3, wherein:
the first tapered sidewall of the first portion of the radiation channeling structure has a first slope;
the second tapered sidewall of the first portion of the radiation channeling structure has a second slope; and
the second slope is opposite in polarity relative to the first slope.

5. The semiconductor device of claim 1, wherein the radiation channeling structure comprises:
a plurality of layers separating the body of the radiation channeling structure from the one or more dielectric layers.

6. The semiconductor device of claim 1, wherein:
a width of an uppermost portion of the radiation channeling structure is larger than a width of a lowermost portion of the radiation channeling structure.

7. The semiconductor device of claim 5, wherein the plurality of layers comprises:
a first oxide layer;
a second oxide layer; and
a nitride layer between the first oxide layer and the second oxide layer, wherein at least one of the first oxide layer, the second oxide layer, or the nitride layer comprise the material at least partially surrounding the body.

8. The semiconductor device of claim 7, wherein:
the nitride layer comprises silicon nitride.

9. The semiconductor device of claim 1, wherein:
the one or more dielectric layers comprise a passivation layer and an inter-metal dielectric (IMD) layer.

10. The semiconductor device of claim 1, comprising:
a dielectric layer between the substrate and the one or more dielectric layers, wherein a bottom surface of the radiation channeling structure is over the dielectric layer.

11. The semiconductor device of claim 10, wherein:
the dielectric layer comprises an interlayer dielectric (ILD) layer.

12. A semiconductor device, comprising:
one or more dielectric layers over a photodiode in a substrate;
a radiation channeling structure extending through the one or more dielectric layers, wherein the radiation channeling structure overlies the photodiode; and
a lens overlying the radiation channeling structure,
wherein:
a first portion of the radiation channeling structure is a first distance from the photodiode;
a second portion of the radiation channeling structure is a second distance from the photodiode;
the first distance is less than the second distance; and
the first portion of the radiation channeling structure has a first tapered sidewall with which a first tapered sidewall of a first dielectric layer of the one or more dielectric layers is aligned.

13. The semiconductor device of claim 12, wherein the radiation channeling structure comprises:
a body; and
a plurality of layers separating the body from the one or more dielectric layers.

14. The semiconductor device of claim 12, wherein:
the first portion of the radiation channeling structure has a second tapered sidewall with which a second tapered sidewall of the first dielectric layer is aligned;
the first portion of the radiation channeling structure has a third tapered sidewall with which a third tapered sidewall of the first dielectric layer is aligned; and
the first portion of the radiation channeling structure has a fourth tapered sidewall with which a fourth tapered sidewall of the first dielectric layer is aligned.

15. The semiconductor device of claim 14, wherein:
the first tapered sidewall of the first portion of the radiation channeling structure has a first slope;
the second tapered sidewall of the first portion of the radiation channeling structure has a second slope;
the third tapered sidewall of the first portion of the radiation channeling structure has a third slope;
the fourth tapered sidewall of the first portion of the radiation channeling structure has a fourth slope;
the second slope is opposite in polarity relative to the first slope; and
the third slope is opposite in polarity relative to the fourth slope.

16. A method for forming a semiconductor device, comprising:
forming a plurality of dielectric layers over a substrate;
forming a trench through one or more dielectric layers of the plurality of dielectric layers, wherein:
the trench overlies a photodiode in the substrate;
a bottom of the trench is defined by a first tapered sidewall of a first dielectric layer of the one or more dielectric layers and a second tapered sidewall of the first dielectric layer;
the first tapered sidewall of the first dielectric layer has a first slope;
the second tapered sidewall of the first dielectric layer has a second slope; and
the second slope is opposite in polarity relative to the first slope; and
forming a plurality of layers, of a radiation channeling structure, in the trench, wherein the plurality of layers comprises:
a first oxide layer;
a second oxide layer; and
a nitride layer between the first oxide layer and the second oxide layer.

17. The method of claim 16, wherein:
the nitride layer comprises silicon nitride.

18. The method of claim 16, comprising:
forming a body, of the radiation channeling structure, in the trench, wherein:
the second oxide layer is between the nitride layer and the body;
the body has a refractive index higher than a refractive index of the second oxide layer; and
sidewalls of the body are aligned with a surface of the second oxide layer.

19. The method of claim 18, comprising:
forming a lens over the plurality of dielectric layers, wherein the lens overlies the radiation channeling structure.

20. The method of claim 19, wherein:
radiation incident upon the lens is channeled through the radiation channeling structure to the photodiode.
